(19) United States
(12) Patent Application Publication
(10) Pub. No.: US 2006/0234502 A1
(43) Pub. Date: Oct. 19, 2006

(54) Method of forming titanium nitride layers

(76) Inventors: Vishwanath Bhat, Boise, ID (US); F. Daniel Gealy, Kuna, ID (US)

Correspondence Address: WILLIAMS, MORGAN & AMERSON, 10333 RICHMOND, SUITE 1100, HOUSTON, TX, 77042, US

(21) Appl. No.: 11/105,096

(22) Filed: Apr. 13, 2005

(51) Int. Cl. H01L 21/44

(52) U.S. Cl. 438/656; 438/685

(57) ABSTRACT

The present invention is generally directed to a method of forming titanium nitride layers. In one illustrative embodiment, the method includes forming a layer of titanium nitride by performing a deposition process, performing an anneal process on the layer of titanium nitride in a chlorine scavenging ambient to define an annealed layer of titanium nitride, and, prior to exposing the annealed layer of titanium nitride to an oxygen-containing ambient, forming a cap layer on the annealed layer of titanium nitride. In another illustrative embodiment, the method includes performing a chemical vapor deposition process in a first process chamber to form a layer of titanium nitride above a semiconducting substrate, transferring the substrate to a second process chamber, performing an anneal process on the layer of titanium nitride in a chlorine scavenging ambient within the second process chamber to produce an anneal layer of titanium nitride, and, prior to exposing the annealed layer of titanium nitride to an oxygen-containing ambient, forming a cap layer on the annealed layer of titanium nitride in the second process chamber.

### BACKGROUND OF THE INVENTION

1. Field of the Invention

The present invention is generally directed to the field of semiconductor device manufacturing processes, and, more particularly, to a Method of forming titanium nitride layers.

2. Description of the Related Art

Integrated circuit devices, e.g., memory devices, logic devices, etc., are produced using mass production techniques. The market for such integrated circuit devices is very competitive. Semiconductor manufacturers are under constant pressure to increase productivity and improve manufacturing efficiencies while maintaining high product integrity.

Titanium nitride (TiN) films or layers are widely employed in the manufacture of many integrated circuit devices. For example, a titanium nitride layer may be employed as a cell electrode in a DRAM (Dynamic Random Access Memory) device. More specifically, as DRAM manufacturers proceed toward adoption of a metal-insulator-metal (MIM) process flow, both the bottom and top cell electrodes may be layers of titanium nitride. Of course, this is but one illustrative example of a situation in which a layer of titanium nitride may be employed in an integrated circuit device.

As indicated above, maximizing manufacturing throughput and efficiencies is a constant desire in manufacturing integrated circuit devices. Traditionally, titanium nitride layers are formed by a chemical vapor deposition (CVD) process or a plasma enhanced chemical vapor deposition (PECVD) process due to the increased throughput using such processes, as compared to other possible processes that might be employed to form a layer of titanium nitride, e.g., atomic layer deposition (ALD), sequential flow deposition (SFD), etc. Such CVD-based processes typically employ a chlorine containing titanium precursor (e.g., TiCl₄ or TiCl₄ with one or more halides replaced with an organic amido group, e.g., TiCl₃ NC₂H₆, etc.). Titanium nitride layers formed by a CVD or PECVD process using such precursors are known to contain a high concentration of chlorine (Cl) in the resulting layer. The high concentration of chlorine is undesirable since it may be detrimental to the performance of some integrated circuit devices. For example, increased chlorine levels may have an adverse effect on the electrical properties of a capacitor and/or increase the sheet resistance (Rₛ) of the resulting layer of titanium nitride.

The chlorine concentration in CVD deposited titanium nitride layers can be reduced by subjecting the layer to an in situ ammonia (NH₃) anneal process in the CVD deposition chamber at the deposition temperature of, for example, approximately 500-680° C. This in situ ammonia anneal in the CVD deposition chamber results in reducing the chlorine levels in the titanium nitride layer to levels comparable to those achieved if the titanium nitride layer is formed using a sequential flow deposition process (SFD). However, SIMS analysis of a layer of titanium nitride subjected to such an in situ ammonia anneal process in the deposition chamber reveals that such layers contained a very high level of oxygen (approximately 1×10²⁰ atoms/cm³) as compared to a CVD titanium nitride layer that was not subjected to the in situ ammonia anneal in the deposition chamber (approximately 1×10¹⁸ atoms/cm³). High levels of oxygen in the resulting titanium nitride layer are undesirable for a variety of reasons, e.g., it results in the layer of titanium nitride having an increased sheet resistance.

The present invention is directed to a device and various methods that may solve, or at least reduce, some or all of the aforementioned problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present invention is generally directed to a method of forming titanium nitride layers. In one illustrative embodiment, the method comprises forming a layer of titanium nitride by performing a deposition process, performing an anneal process on the layer of titanium nitride in a chlorine scavenging ambient to define an annealed layer of titanium nitride, and, prior to exposing the annealed layer of titanium nitride to an oxygen containing ambient, forming a cap layer on the annealed layer of titanium nitride.

In another illustrative embodiment, the method comprises performing a deposition process in a first process chamber to form a layer of titanium nitride above a semiconducting substrate, transferring the substrate to a second process chamber, performing an anneal process on the layer of titanium nitride in a chlorine scavenging ambient within the second process chamber to produce an anneal layer of titanium nitride, and, prior to exposing the annealed layer of titanium nitride to an oxygen containing ambient, forming a cap layer on the annealed layer of titanium nitride in the second process chamber.

In yet another illustrative embodiment, the method comprises performing a chemical vapor deposition process in a first process chamber to deposit a layer of titanium nitride above a semiconducting substrate, transferring the substrate to a second process chamber, performing an anneal process at a temperature within the range of approximately 500-650° C. on the layer of titanium nitride in a chlorine scavenging ambient within the second process chamber to produce an annealed layer of titanium nitride, and, prior to exposing the annealed layer of titanium nitride to an oxygen containing ambient, depositing a cap layer comprised of polysilicon on the annealed layer of titanium nitride in the second process chamber.

### BRIEF DESCRIPTION OF THE DRAWINGS

The invention may be understood by reference to the following description taken in conjunction with the accompanying drawings, in which like reference numerals identify like elements, and in which:

FIG. 1 is a cross-sectional view of an illustrative layer of titanium nitride having a cap layer formed thereabove in accordance with one illustrative embodiment of the present invention;

FIG. 2 is a schematic depiction of one illustrative process flow that may be performed in accordance with the present invention;

FIG. 3 is a schematic depiction of another illustrative process flow that may be performed in accordance with the present invention;

FIG. 4 is a cross-sectional view of a portion of an illustrative integrated circuit device in accordance with one illustrative embodiment of the present invention; and

FIG. 5 is a cross-sectional view of a portion of another illustrative integrated circuit device in accordance with one illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

In general, the present invention is directed to a novel method of forming a layer of titanium nitride (TiN), and to various integrated circuit devices that may employ such a layer of titanium nitride. As will be recognized by those skilled in the art after a complete reading of the present application, the present invention has broad application and it may be employed in a variety of contexts and employed with a variety of integrated circuit devices. Thus, the present invention should not be considered as limited to the illustrative embodiments disclosed herein.

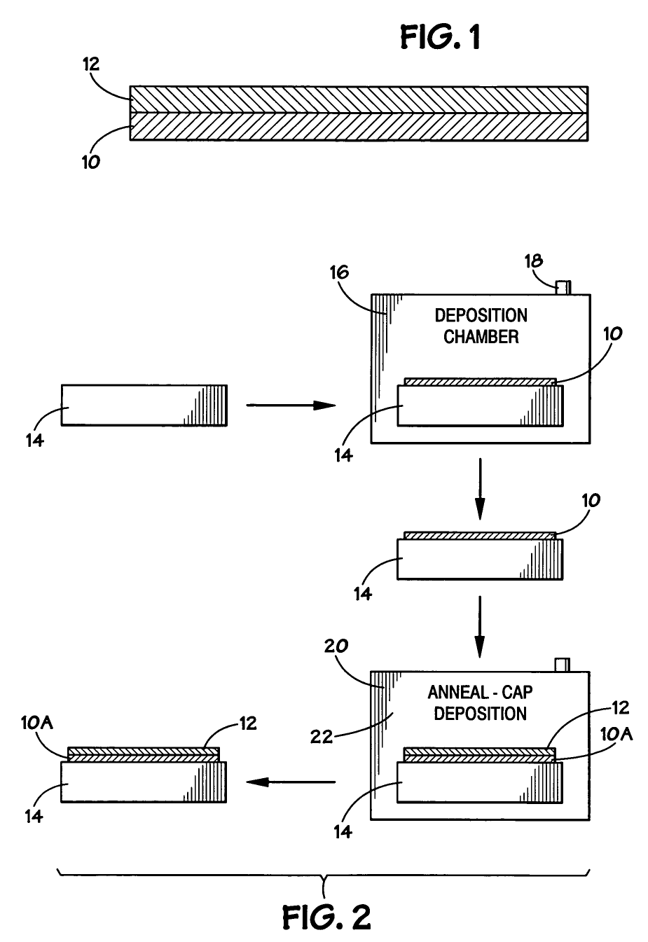

FIG. 1 is a cross-sectional view of a portion of a layer of titanium nitride 10 having a cap layer 12 formed thereabove. The titanium nitride layer 10 may be formed to any desired thickness, and it may be formed by any of a variety of deposition processes employing a chlorine containing titanium precursor, e.g., TiCl₄, TiCl₃ NC₂H₆, etc. For example, the layer of titanium nitride may be formed by performing a chemical vapor deposition (CVD) process, a plasma enhanced chemical vapor deposition (PECVD) process, a pulsed CVD process, an atomic layer deposition (ALD) process, etc. It should be understood that when reference is made herein to a “chemical vapor deposition process” or “CVD-based process” that such a phrase includes all forms of chemical vapor deposition processes. As indicated in the background section of this application, a CVD-deposited titanium nitride layer subjected to an in situ ammonia anneal process in the CVD deposition chamber at the deposition temperature was observed to contain high levels of oxygen. Sheet resistance measurements of the ammonia annealed CVD-deposited titanium nitride layer indicated that the sheet resistance increased with time, and that oxygen was absorbed into the ammonium annealed CVD-deposited layer of titanium nitride soon after the layer was exposed to ambient conditions.

One illustrative process flow for forming a layer of titanium nitride in accordance with the present invention will now be described with reference to FIG. 2. As shown therein, an illustrative semiconducting substrate 14 is provided to a first process chamber 16 wherein the layer of titanium nitride 10 will be formed above the semiconducting substrate 14. As indicated previously, the deposition chamber 16 may be any of a variety of known CVD, PECVD or ALD chambers commonly employed in the industry. A chlorine containing titanium precursor may be introduced into the chamber 16 via the schematically depicted inlet 18. Traditional deposition process parameters may be used to form the titanium nitride layer 10. As stated previously, the titanium nitride layer 10 depicted herein may be formed at any level above the semiconducting substrate or within a trench or opening formed in the substrate 14.

As indicated in FIG. 2, in one illustrative process flow, after the titanium nitride layer 10 is formed in the chamber 16, the substrate 14 (with the titanium nitride layer 10 formed thereabove) is removed from the first process chamber 16 and sent to a second process chamber 20. Initially, the titanium nitride layer 10 will be subjected to an anneal process in a chlorine scavenging ambient 22 established within the second process chamber 20. For example, the chlorine scavenging ambient 22 may be created by introducing ammonia (NH₃), hydrazine (N₂H₄), a hydrazine derivative (such as, for example, monomethyl hydrazine or dimethyl hydrazine) or silane (SiH₄) into the second process chamber 20. In one particularly illustrative example, the chlorine scavenging ambient 22 is ammonia, and it may be at a partial pressure in the range of 0.5-10 T.

In one particularly illustrative example, where ammonia or hydrazine is employed as the chlorine scavenging ambient 22, the titanium nitride layer 10 may be subjected to an anneal at a temperature within a range of approximately 500-650° C. in the chlorine scavenging ambient 22 for a duration ranging from approximately 5-20 minutes. If silane is employed to establish the chlorine scavenging ambient 22, the anneal process may be performed at a lower temperature, e.g., approximately 400-500° C., to prevent formation of polysilicon until it is desired to do so. Performance of this anneal process results in an annealed layer of titanium nitride 10A. The anneal process in the chlorine scavenging ambient 22 reduces the level of chlorine in the annealed titanium nitride layer 10A to acceptable levels, e.g., approximately 1-3 atomic %.

After the anneal process is performed, and before the annealed layer of titanium nitride 10A is exposed to an oxygen containing environment, e.g., ambient conditions, the cap layer 12 is formed above the annealed titanium nitride layer 10A. That is, the titanium nitride layer 10 is subjected to an in situ anneal in the chlorine scavenging ambient 22 in the second process chamber 20, followed by the formation of the cap layer 12 in the second process chamber 20. One purpose of the cap layer 12 is to prevent the annealed titanium nitride layer 10A from being exposed to an oxygen containing environment. Of course, depending upon the particular application, the cap layer 12 may serve other purposes on a semiconductor device.

The cap layer 12 may be comprised of a variety of materials and it may be formed using a variety of known techniques, e.g., CVD, PECVD, etc. Moreover, it may be comprised of a conductive or a non-conductive material and it may be formed to any desired thickness. In one illustrative embodiment, the cap layer 12 may be comprised of a conductive material such as polysilicon, and it may be formed by introducing silane into the deposition chamber 20 after the chlorine scavenging ambient 22 is evacuated from the chamber 20 after the anneal process is performed. In one illustrative process flow, silane may be employed to establish the chlorine scavenging ambient 22. In that case, after the anneal process is performed at, for example 400-500° C., the temperature may be increased above 540° C. such that a layer of polysilicon, i.e., the cap layer 12, is formed on the annealed layer of titanium nitride 10A. In one particularly illustrative embodiment, the cap layer 12 is comprised of polysilicon and it has a thickness of approximately 100-250 Å. In another illustrative embodiment, the cap layer 12 may be comprised of a non-conductive material such as silicon nitride.

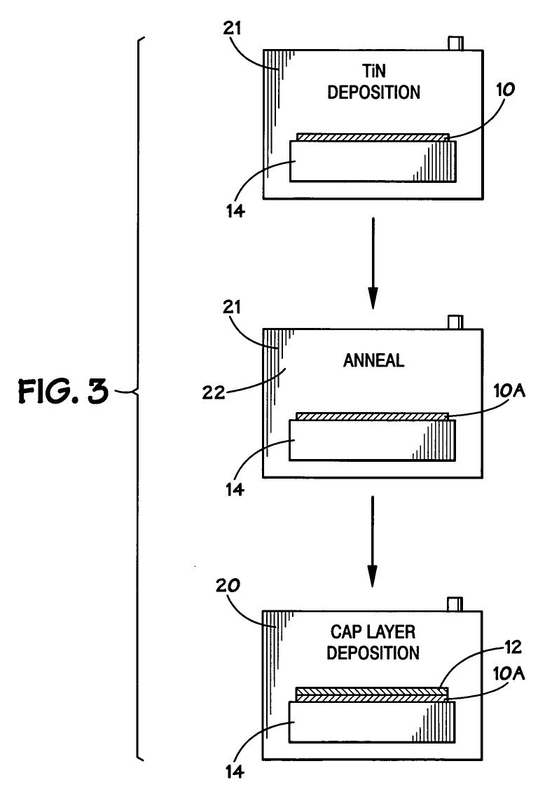

In the illustrative process flow described in FIG. 2, two deposition chambers (16 and 20) are employed to form the combination of the anneal titanium nitride layer 10A and the cap layer 12. However, depending upon the particular application, the methodologies described above may be performed in a single deposition chamber 21, as illustratively depicted in FIG. 3. The chamber 21 may be any type of chamber suitable for forming both the layer of titanium nitride 10 and the cap layer 12, and for performing the anneal process on the layer of titanium nitride 10 in a chlorine scavenging ambient 22. The various sequential steps that are performed in the deposition chamber 21 are depicted in FIG. 3. As discussed above, the first step involves forming the titanium nitride layer 10 in the chamber 21, followed by establishing the chlorine scavenging ambient 22 in the chamber 21. Thereafter, the layer of titanium nitride 10 is subjected to an anneal process as described above to define an annealed layer of titanium nitride 10A. After the anneal process is performed, and prior to exposing the annealed layer of titanium nitride 10A to an oxygen-containing environment, e.g., ambient conditions, the cap layer 12 is deposited on the annealed layer of titanium nitride 10A. Using this methodology, formation of the annealed layer of titanium nitride 10A and the cap layer 12 as well as performance of the anneal process may be performed in a single process chamber.

The titanium nitride layer 10A formed in accordance with the illustrative methodologies described herein may exhibit reduced levels of chlorine and/or lower levels of oxygen relative to titanium nitride layers formed in accordance with the prior art techniques described herein. By way of example only, the titanium nitride layer 10A, having the cap layer 12 formed thereabove, may have a chlorine concentration ranging from approximately 2-3% and an oxygen concentration ranging from approximately 1×10¹⁸−2×10¹⁹ atoms/cm³. Of course, such concentration ranges are provided by way of example only, and they should not be considered a limitation of the present invention. Formation of titanium nitride layers having reduced levels of oxygen using high throughput chemical vapor deposition processes makes such layers highly desirable for inclusion in many integrated circuit products.

After the cap layer 12 is formed, additional known processing operations may be performed to form integrated circuit devices on the substrate 14. As indicated previously, the annealed titanium nitride layer 10A disclosed herein may be part of any type of integrated circuit device or portions thereof, e.g., memory devices, logic devices, transistors, capacitors, resistors, etc.

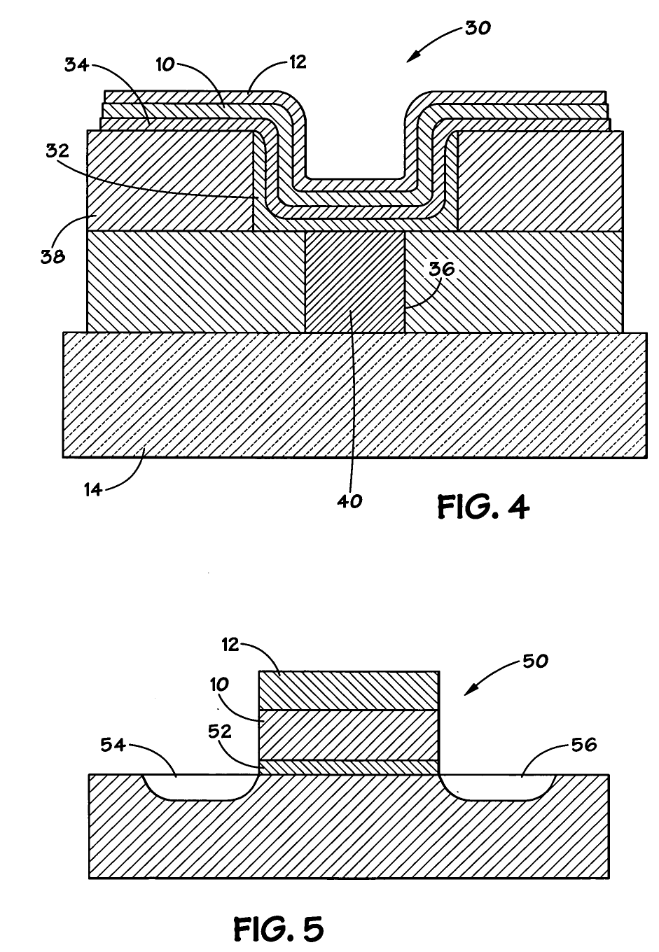

FIG. 4 depicts a portion of an illustrative capacitor 30 wherein a titanium nitride layer 10 may be employed. As shown therein, the capacitor 30, a so-called container capacitor, is comprised of a first layer of titanium nitride 32, an insulating layer 34, a titanium nitride layer 10 and a cap layer 12. The various layers 32, 34, 10 and 12 are at least partially positioned in a trench 36 formed in a layer of insulating material 38. Also depicted in FIG. 4 is a conductive plug 40 formed in another layer of insulating material 42. An illustrative substrate 14 is also depicted in FIG. 4. The insulating layers described above may be comprised of a variety of known insulating materials, e.g., silicon dioxide, silicon nitride, etc.

In the illustrative embodiment depicted in FIG. 4, the capacitor 30 has a metal-insulator-metal structure by virtue of the titanium nitride layer 32, the insulating layer 34, and the titanium nitride layer 10. If desired, the capacitor 30 could be of metal-insulator-semiconductor structure if the titanium nitride layer 32 were replaced with a layer of polysilicon. The various steps employed in forming the illustrative capacitor 30 are well known to those skilled in the art. As indicated in FIG. 4, the capacitor 30 employs the titanium nitride layer 10 and cap layer 12 formed in accordance with the novel techniques disclosed herein. Depending upon the particular application and space constraints, the titanium nitride layer 32 depicted in FIG. 4 could also be replaced with a titanium nitride layer 10 having a cap layer 12 formed thereabove.

FIG. 5 depicts a portion of another illustrative integrated circuit device wherein a titanium nitride layer 10 and cap layer 12 in accordance with the present invention may be employed. Depicted therein is a portion of an illustrative word line 50. The word line 50 comprises an insulating layer 52, a layer of titanium nitride 10, a cap layer 12, a source region 54 and a drain region 56.

The present invention is generally directed to a method of forming titanium nitride layers. In one illustrative embodiment, the method comprises forming a layer of titanium nitride by performing a deposition process, performing an anneal process on the layer of titanium nitride in a chlorine scavenging ambient to define an annealed layer of titanium nitride, and, prior to exposing the annealed layer of titanium nitride to an oxygen containing ambient, forming a cap layer on the annealed layer of titanium nitride.

In another illustrative embodiment, the method comprises performing a deposition process in a first process chamber to form a layer of titanium nitride above a semiconducting substrate, transferring the substrate to a second process chamber, performing an anneal process on the layer of titanium nitride in a chlorine scavenging ambient within the second process chamber to produce an anneal layer of titanium nitride, and, prior to exposing the annealed layer of titanium nitride to an oxygen containing ambient, forming a cap layer on the annealed layer of titanium nitride in the second process chamber.

In yet another illustrative embodiment, the method comprises performing a chemical vapor deposition process in a first process chamber to deposit a layer of titanium nitride above a semiconducting substrate, transferring the substrate to a second process chamber, performing an anneal process at a temperature within the range of approximately 500-650° C. on the layer of titanium nitride in a chlorine scavenging ambient within the second process chamber to produce an annealed layer of titanium nitride, and, prior to exposing the annealed layer of titanium nitride to an oxygen containing ambient, depositing a cap layer comprised of polysilicon on the annealed layer of titanium nitride in the second process chamber.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a layer of titanium nitride by performing a deposition process;
performing an anneal process on said layer of titanium nitride in a chlorine scavenging ambient to define an annealed layer of titanium nitride; and
prior to exposing said annealed layer of titanium nitride to an oxygen containing ambient, forming a cap layer on said annealed layer of titanium nitride.

2. The method of claim 1, wherein said acts of forming said layer of titanium nitride, performing said anneal process and forming said cap layer are all performed in a single process chamber.

3. The method of claim 1, wherein forming a layer of titanium nitride by performing a deposition process comprises forming a layer of titanium nitride by performing a deposition process in a first process chamber, and wherein the acts of performing said anneal process and forming said cap layer are performed in a second process chamber.

4. The method of claim 1, wherein said anneal process is performed at a temperature ranging from 500-650° C.

5. The method of claim 1, wherein said anneal process is performed for a duration ranging from approximately 5-20 minutes.

6. The method of claim 1, wherein said chlorine scavenging ambient comprises at least one of ammonia, hydrazine, a hydrazine derivative and silane.

7. The method of claim 1, wherein said chlorine scavenging ambient is silane and said anneal temperature ranges from 400-500° C.

8. The method of claim 1, wherein forming a layer of titanium nitride by performing a deposition process comprises forming a layer of titanium nitride by performing a deposition process using a chlorine containing precursor.

9. The method of claim 1, wherein said cap layer comprises at least one of polysilicon and silicon nitride.

10. The method of claim 1, wherein forming a layer of titanium nitride by performing a deposition process comprises forming a layer of titanium nitride by performing a chemical vapor deposition process.

11. The method of claim 1, wherein forming said cap layer comprises performing a chemical vapor deposition process to form said cap layer.

12. The method of claim 1, further comprising performing at least one additional process step to form an integrated circuit device comprising said annealed layer of titanium nitride and said cap layer.

13. The method of claim 12, wherein said integrated circuit device comprises at least one of a capacitor and a word line on a memory device.

14. A method, comprising:
performing a deposition process in a first process chamber to form a layer of titanium nitride above a semiconducting substrate;
transferring said substrate to a second process chamber;
performing an anneal process on said layer of titanium nitride in a chlorine scavenging ambient within said second process chamber to define an annealed layer of titanium nitride; and
prior to exposing said annealed layer of titanium nitride to an oxygen containing ambient, forming a cap layer on said annealed layer of titanium nitride in said second process chamber.

15. The method of claim 14, wherein said anneal process is performed at a temperature ranging from 500-650° C.

16. The method of claim 14, wherein said anneal process is performed for a duration ranging from approximately 5-20 minutes.

17. The method of claim 14, wherein said chlorine scavenging ambient comprises at least one of ammonia, hydrazine, a hydrazine derivative and silane.

18. The method of claim 14, wherein said chlorine scavenging ambient is silane and said anneal temperature ranges from 400-500° C.

19. The method of claim 14, wherein said cap layer comprises at least one of a conductive material and a non-conductive material.

20. The method of claim 14, wherein forming said cap layer comprises performing a chemical vapor deposition process to form said cap layer.

21. The method of claim 14, further comprising performing at least one additional process step to form an integrated circuit device comprising said annealed layer of titanium nitride and said cap layer.

22. The method of claim 21, wherein said integrated circuit device comprises at least one of a capacitor and a word line on a memory device.

23. A method, comprising:
performing a chemical vapor deposition process in a first process chamber to deposit a layer of titanium nitride above a semiconducting substrate;
transferring said substrate to a second process chamber;
performing an anneal process at a temperature within the range of approximately 500-650° C. on said layer of titanium nitride in a chlorine scavenging ambient within said second process chamber to produce an annealed layer of titanium nitride; and
prior to exposing said annealed layer of titanium nitride to an oxygen containing ambient, depositing a cap layer comprised of polysilicon on said annealed layer of titanium nitride in said second process chamber.

24. The method of claim 23, wherein said anneal process is performed for a duration ranging from approximately 5-20 minutes.

25. The method of claim 23, wherein said chlorine scavenging ambient comprises at least one of ammonia, hydrazine, a hydrazine derivative and silane.

26. The method of claim 23, wherein said chlorine scavenging ambient is silane and said anneal temperature ranges from 400-500° C.

27. The method of claim 23, further comprising performing at least one additional process step to form a semiconductor device comprising said annealed layer of titanium nitride and said cap layer.

28. The method of claim 27, wherein said semiconductor device comprises at least one of a capacitor and a word line on a memory device.
